(19) United States
(12) Patent Application Publication
(10) Pub. No.: US 2026/0280267 A1
(43) Pub. Date: Sep. 17, 2026

(54) SWITCH DEVICE AND METHOD FOR OPERATING A SWITCH DEVICE

(71) Applicant: Siemens Aktiengesellschaft, München (DE)

(72) Inventors: Stephan Jonas, Neunburg (DE); Dominic Malane, Eichstätt (DE); Norbert Reichenbach, Amberg (DE); Julian Stefan Breiter, Regensburg (DE)

(21) Appl. No.: 19/167,461

(22) PCT Filed: Jan. 22, 2024
(86) PCT No.: PCT/EP2024/051413

§ 371 Date: Sep. 22, 2025

(30) Foreign Application Priority Data
Mar. 21, 2023 (DE) 10 2023 202 470.5

(51) Int. Cl. H02H 3/02; H02H 3/08; H03K 17/0814

(52) U.S. Cl. CPC H02H 3/023; H02H 3/083; H03K 17/08148; H03K 2217/0009; H03K 2217/0027

(57) ABSTRACT

A switch device for controlling a flow of electric energy from an energy source to a load has conductor inputs connecting to the energy source, conductor outputs connecting to the load, and conductor current paths which electrically connect the conductor inputs to the conductor outputs in a bijective manner within the switch device. Switch elements arranged in the conductor current paths can switch a current flow through the outer conductor current path. Overvoltage limiting elements are connected in parallel to the switch elements, and a control unit actuates the switch elements. Short-circuiting switches can be actuated by the control unit to a current-conducting state, where they conductively connect the conductor outputs of the switch device a) to each other and/or b) to a ground conductor or a neutral conductor of the energy source.

The present invention relates to a switch device for controlling an electrical energy flux from an electrical energy source to an electrical energy load. The present invention further relates to a method for operating a switch device of this type.

Switch devices are employed for the controlled supply of electrical loads with electrical energy from an electric power source. Within a switch device, electric current paths are configured, via which electric current is routed from an input of the switch device to an output of the switch device, such that electrical energy is conducted from the electrical energy source to the load. In the current paths, switch elements for the switch-on and switch-off of the electric current are located. The rapid switching capacity of state-of-the-art electronic switch elements, such as MOSFET transistors, can be employed for the interruption of a rapidly rising current in output-side current circuits, e.g. associated with a short-circuit, within a very short space of time.

In the event of the rapid interruption of currents, as a result of inductances in the current circuits, a very high voltage stress can occur in electronic switch elements which, in the absence of appropriate protective measures, would result in the destruction thereof. Consequently, for the protection of electronic switch elements, overvoltage limiting elements, also described as overvoltage limiters, are arranged in parallel thereto. The voltage-limiting action of overvoltage limiting elements is achieved wherein the latter, in excess of a stipulated voltage limiting value, are rendered electrically conductive, such that any further voltage rise thereon is restricted. The voltage limiting value is selected such that a maximum permissible voltage on the electronic switching elements is not exceeded during the limiting process.

It is necessary for overvoltage limiting elements to be dimensioned such that the full conversion thereby of the magnetic energy of inductances which are present in the short-circuit into heat is enabled, without sustaining damage. The dimensioning of overvoltage limiting elements is thus critical, on the grounds that this dimensioning is dependent upon magnitude of inductances in the entire electrical assembly, and thus upon multiple parameters.

One issue for the dimensioning of overvoltage limiting elements is the necessity for the adoption of appropriate assumptions for the length of load connection lines and the type of load, together with identification of unfavorable switch-off events, in order to enable the dimensioning of overvoltage limiting elements to an acceptable magnitude.

A further problem for the dimensioning of overvoltage limiting elements is posed by the normal switch-off of an asynchronous motor wherein, by the interaction of load output terminal voltages and voltages on the three-phase AC grid, increased voltages occur on switching elements which, although not resulting in the damage thereof, generate a response of overvoltage limiting elements, on the grounds of the necessity that the voltage limiting value thereof is lower than the maximum permissible switching element voltage. This is attributable to tolerances in overvoltage limiting elements, and the non-ideal limiting function thereof.

In practice, on the grounds of relatively wide tolerance bands and the non-ideal limiting characteristic, establishment of the voltage limiting value of overvoltage limiting elements is not simple, and is further exacerbated by the temperature-dependence of the voltage limiting value, such that the preferred voltage limiting value frequently represents a compromise which incorporates gray areas, within which the limiting function operates in a sub-optimal manner only.

The object of the present invention is an improved over-voltage protection of electronic switching elements.

According to the invention, this object is fulfilled by a switch device having the features disclosed in claim 1. According to the invention, this object is further fulfilled by a method having the features disclosed in claim 10.

The switch device according to the invention is employed for controlling an electrical energy flux from an energy source to a load. The energy source is also described as a current source. The energy source can be a single-phase or multi-phase, in general a n-phase current source. The load is also described as a current load. The load can be a motor load, e.g. an induction motor, or a non-motor load, e.g. an electric heater or a lighting device. The switch device comprises n phase conductor inputs for electrically connecting to the energy source; the phase conductor inputs are also described as phase inputs. The switch device comprises n phase conductor outputs for electrically connecting to the load; the phase conductor outputs are also described as phase outputs. The switch device comprises n phase conductor current paths which, within the switch device, electrically connect the n phase conductor inputs of the switch device to the n phase conductor outputs of the switch device, in a bijective arrangement. The phase conductor current paths thus form supply lines which connect the phase conductor inputs and the phase conductor outputs for the transmission of power from the energy source to the load, wherein each supply line corresponds to one phase of the current load. The energy source can deliver a single-phase or multi-phase power supply; for example, the energy source can be a three-phase AC grid or three-phase AC system, from which one current phase is transmitted via a phase conductor current path of the switch device to the load, or from which three current phases, via one of three phase conductor current paths of the switch device respectively, is transmitted to the load. The energy source can also be configured in the form of any other arbitrary single-phase or multi-phase voltage source, e.g. on the basis of galvanic elements. The switch device comprises n switching elements, each of which can switch an electric current flowing through a phase conductor current path. One of the n switching elements respectively is arranged in the n phase conductor current paths. The switch device comprises n overvoltage limiting elements, each of which is parallel-connected to one of the n switching elements; one overvoltage limiting element is thus respectively assigned to each switching element. Overvoltage limiting elements execute a voltage-limiting function wherein, in excess of a specified voltage value, which is described as the voltage limiting value, they assume a conducting state and thus conduct current, such that any further voltage rise thereon is relatively restricted. The voltage limiting value is thus selected such that a maximum permissible voltage, the application of which to the switching elements is permitted, is not exceeded during the limiting process. The switch device comprises a control unit for actuating the switching elements. The switch device moreover comprises short-circuiting switches, which switches are actuatable by means of the control unit and are arranged in the switch device such that, in a current-conducting state thereof, they connect the n phase conductor outputs, in an electrically conductive manner, a) to one another and/or b) to a ground conductor or neutral conductor of the energy source. A distinction can thus be drawn between three variants:
Variant i): the short-circuiting switches are arranged in the switch device and are actuated by the control unit such that the short-circuiting switches, in the current-conducting state thereof, interconnect the n phase conductor outputs of the switch device in an electrically conductive manner.
Variant ii): the short-circuiting switches are arranged in the switch device and are actuated by the control unit such that the short-circuiting switches, in the current-conducting state thereof, connect the n phase conductor outputs of the switch device to one further conductor in an electrically conductive manner, wherein the further conductor is a ground conductor or a neutral conductor of the energy source.
Variant iii): the short-circuiting switches are arranged in the switch device and are actuated by the control unit such that the short-circuiting switches, in the current-conducting state thereof, execute the electrically conductive interconnection of the n phase conductor outputs of the switch device, and execute the electrically conductive connection thereof to one further conductor, wherein the further conductor is a ground conductor or a neutral conductor of the energy source.

The totality of phase conductors, neutral conductors and ground conductors is described as a conductor system.

The switch device according to the invention can be connected in an electrical supply line of an electrical load, i.e. in a “load spur”, and employed for switching and/or contacting the electrical load; consequently, the switch device according to the invention can also be alternatively described as a switching and protective device. Contacting of the electrical load by means of the switch device is thus employed for protecting the electrical load, and the supply line which is routed to the electrical load, against unacceptably high currents. A supply line of an electrical load is an electrical line via which the load is supplied with electrical energy. Examples of the employment of a switch device include applications thereof as a circuit-breaker, contactor, relay or motor starter, i.e. as a switch device for the start-up of an electric motor.

The method according to the invention is employed for operating a switch device which controls an electrical energy flux from an energy source to a load. Within the switch device, n phase conductor current paths are provided, in each of which a parallel-connected arrangement of a switching element and an overvoltage limiting element is arranged. The switching element can be actuated such that the switchover thereof is executed from a current-conducting circuit state to a non-conducting circuit state, or from a non-conducting circuit state to a current-conducting circuit state. The n phase conductor current paths electrically connect n phase conductor inputs of the switch device to n phase conductor outputs of the switch device, in a bijective arrangement. The n phase conductor inputs and the n phase conductor outputs of the switch device are appropriate for electrically connecting to the load. The method comprises a step in which the switching elements are actuated such that the switching elements assume a current-conducting state, and a current flux via the respective phase conductor current path is enabled. The method comprises a further step in which the current flux in the phase conductor current paths is interrupted, wherein the switching elements are actuated such that they execute a switchover from a current-conducting circuit state thereof to a non-conducting circuit state thereof. The method comprises one further step wherein, further to the switchover of the switching elements to the non-conducting state thereof, short-circuiting switches of the switch device are actuated such that they execute a switchover to a current-conducting circuit state; the short-circuiting switches are arranged in the switch device such that, in the current-conducting circuit state thereof, they connect the n phase conductor outputs of the switch device, in an electrically conductive manner, a) to one another and/or b) to a ground conductor or neutral conductor of the energy source. The short-circuiting switches are also described as output short-circuiters, or simply as short-circuiters.

The invention is based upon the finding to the effect that, by means of short-circuiting switches in the switch device, which switches short-circuit the phase conductor outputs of the switch device, further to the switch-out of a short-circuit or further to a normal and routine switch-off operation, with respect to one another and/or with respect to a neutral or ground conductor, it is enabled that the magnetic energy of inductances, which are present in an electric power grid comprising the connection lines between the energy source and the switch device and incorporating the connection lines between the switch device and the load, undergoes decay in two current circuits, of which only one is routed through the overvoltage limiting elements. In comparison with a switch-off operation in the absence of output short-circuiters, in the case of a switch-off by means of output short-circuiters, the conduction interval in overvoltage limiting elements is substantially shorter, as only the decay of the magnetic energy of inductances of the input connection lines and of the electrical energy source is required. Conversion of magnetic energy on the load side which, depending upon the conductor length and the type of load, can be very high, into heat by means of the overvoltage limiting elements is no longer required. Overvoltage limiting elements can thus be dimensioned with a substantially lower rating, as only the design rating thereof for the comparatively small inductances of the input connection lines and the electric voltage source is required.

Voltages generated by the load upon the switch-off thereof are thus short-circuited by the short-circuiters, and do not act on the switching elements. As a result, overvoltage limiting elements are only active for a short time and, in consequence, only undergo a relatively limited heat-up.

According to conventional solutions, which operate without short-circuiters according to the invention, it is necessary for overvoltage limiting elements to be dimensioned for a wide range of inductance which is dictated by the length of load connection lines and the type of load. Heavy-duty, voluminous and thus expensive overvoltage limiting elements are thus required, which elements significantly increase the structural space occupied by the switch device. Alternatively, it is necessary for limiting conditions to be stipulated for the length of load connection lines and the type of load, which conditions must then be incorporated in operating instructions, thus restricting universal application.

By means of the simultaneous switch-off of switching elements and the simultaneous switch-on of short-circuiters, the mode of operation for all short-circuits which can potentially occur between two arbitrary electrical phases is identical wherein, even in the event of a simultaneous short-circuit on all three electrical phases, the load-relief function of overvoltage limiting elements is maintained.

In addition to the function for the load relief of over voltage limiting elements upon the switch-off of a current in the load circuit, short-circuiters can also be switched in further to a normal switch-off operation, immediately the output currents assume a zero value. In the case of normal switch-off operations, the voltage generated by the load, particularly in the case of a motor, can result in an increased voltage stress of switching elements, which must consequently be rated for this purpose. Short-circuiters prevent any perturbation of switching elements by voltages which are generated further to the switch-off of the load. In the case of an asynchronous motor, these are voltages on the output terminals thereof, which voltages can no longer be formed, such that any increased voltage stress of switching elements associated with the motor can no longer occur. As a result, electronic switching elements having a lower off-state voltage can be preferred and, at the same time, tolerance issues associated with the selection of the voltage limiting value of the overvoltage limiting elements can be attenuated. Switching elements, with respect to the dielectric withstand thereof, can be dimensioned with a lower rating, which rating, firstly, is associated with cost advantages and, secondly, switching elements having a lower dielectric withstand generate lower electrical losses during the conduction of electric current, such that the evacuation of less heat is required. Cooling effort is reduced as a result, and smaller housings for switch devices are thus enabled.

Advantageous configurations and further developments of the invention are disclosed in the dependent claims.

According to a preferred configuration of the invention, the switch device comprises an (n+1)^{th} input for electrically connecting to a ground conductor or a neutral conductor of the energy source. One or more of the short-circuiting switches are arranged such that, in a current-conducting state, they connect the n phase conductor outputs in an electrically conductive manner to the (n+1)^{th} input. This configuration provides an advantage, in that the solution according to the invention functions for arbitrary short-circuits and ground faults in the entire load circuit, and thus both in load connection lines and within the load: short-circuits can thus occur between individual or multiple electrical phases, and ground faults on one or more electrical phases routed to a grounded metallic conductor, without compromising the above-mentioned mode of operation according to the invention.

According to a preferred configuration of the invention, the switch device comprises a (n+1)^{th} output for electrically connecting to a ground conductor or to a neutral conductor of the load, and a (n+1)^{th} current path which, within the switch device, electrically connects the (n+1)^{th} input to the (n+1)^{th} output, and thus forms a ground or neutral conductor connection within the switch device. As the ground conductor is led through the switch device, current flowing through the ground conductor can be measured and employed for monitoring the condition of electrical insulation on the load side, comprised of the load connection lines and the load.

For the monitoring of current in the ground conductor, it is moreover advantageous that the short-circuiter which is routed to the ground conductor is only actuated if required, i.e. only in the event of a ground fault, together with other short-circuiters between current-carrying current paths, and can otherwise remain switched-off at all times. As a result, leakage currents from electrical phases to the ground conductor can be minimized.

A switch device having a neutral conductor terminal enables a facility, in normal operation, for controlling loads having a different energy take-up in each of the three electrical phases. The neutral conductor ensures that, on each of the individual loads, the same voltage is applied in the three electrical phases. This enables a separate and independent control of three loads in the electrical phases. Accordingly, each of the three loads can be switched-on and switched-off at different time intervals; additionally, switching elements can thus be switched-on and switched-off in a mutually independent manner. Upon the switch-off of an electrical phase, in order to withhold the voltage generated by the load from the switching element, a short-circuiter is connected from each output of the switch device to the neutral conductor. A short-circuiter is thus assigned to each switching element, such that each switching element, independently of the circuit state of the other two switching elements, is protected in the event of switch-off.

According to a preferred configuration of the invention, from each of the above-mentioned n phase conductor outputs, a short-circuiting switch is routed to the (n+1)^{th} input. The fact that each of the short-circuiters present is routed to the ground conductor, such that the three short-circuiters assume a common connection point, can be advantageous for the actuation of short-circuiters on the grounds that, as a result of the common connection point, a single actuating voltage can be simultaneously employed for all three short-circuiters.

According to a preferred configuration of the invention, the switch device comprises a current measurement device for measuring the current in the ground or neutral conductor connection. The input-side earth fault current decays rapidly further to the switch-on of the short-circuiter, whereas the load-side ground fault current flows for substantially longer, before assuming a value of zero. The overvoltage limiting element assumes a limited load and, as described above, can be dimensioned with a low rating. As the ground conductor is led through the switch device, current flowing through the ground conductor can be measured and employed for monitoring the condition of electrical insulation on the load side, comprised of the load connection lines and the load. By way of distinction from the case in which the ground fault current can be measured directly in the ground conductor, and only flows in the event of a fault, ground current measurement in the case of a connected neutral conductor is only possible in an indirect manner, and is consequently affected by a higher degree of inaccuracy. In this case, it is necessary for the ground fault current to be ascertained by totalizing the four currents flowing out of the switch device. If no ground fault in is force, in an ideal case, the total of these four currents will be equal to zero.

According to a preferred configuration of the invention, the control unit is designed, on the basis of the measured current in the ground conductor connection, to ascertain a condition of electrical insulation of the load. As the ground conductor is led through the switch device, current flowing through the ground conductor can be measured and employed for monitoring the condition of electrical insulation on the load side, comprised of the load connection lines and the load. This enables a prompt detection of insulation faults and a reporting thereof to the operator of the switch device.

According to a preferred configuration of the invention, the control unit is designed, on the basis of the measured current in the neutral conductor connection, and in combination with other measured currents flowing to the phase conductor outputs, to calculate a ground fault current which is employed for monitoring the condition of electrical insulation of the load. In configurations in which the neutral conductor is led through the switch device, the current in the neutral conductor can be measured and the condition of electrical insulation of the connected load appraised on the basis thereof. This enables a prompt detection of insulation faults and a reporting thereof to the operator of the switch device.

According to a preferred configuration of the invention, the switch device comprises current sensors for the acquisition of measured values of current intensity in at least one of the current paths, and transmission means for transmitting measured values to the control unit.

According to a preferred configuration of the invention, the short-circuiting switches are electronic components. This is advantageous, on the grounds that electronic components can be switched on in a significantly temporally more rapid and more accurate manner than mechanical switching elements. The time interval between the assumption of a zero value by switching element currents and the switch-on of short-circuiters can thus be minimized, and the time during which overvoltage limiting elements are thermally loaded thus additionally reduced. Short-circuiting switches are electronic switches which execute the function of an electromechanical switch, but which comprise no moving parts. Short-circuiting switches are switchable to a high-ohmic state, for preventing a current flux, or to a low-ohmic state, for enabling a current flux in a current path; to this end, semiconductor-based switching elements such as field-effect transistors (FETs), MOSFETs (e.g. based upon silicon, gallium nitride, or silicon carbide), IGBTs, bipolar transistors or diodes can be employed. An electronic switching element, additionally to a semiconductor switch, can comprise a protective element for the semiconductor switch.

According to a preferred configuration of the invention, short-circuiting switching elements are electronic components of the MOSFET, IGBT, thyristor, TRIAC or transistor type. By way of electronic components for short-circuiting switches, thyristors and TRIACs are particularly appropriate in the event that the electrical energy source generates AC voltages, as thyristors and TRIACs spontaneously interrupt the current flux, once the current has fallen below a specific threshold. Moreover, these components assume a high short-term current loading capability. As a result, maximum short-circuit current values occurring in the range of 300 to 600 A can be conducted using cost-effective components in a lower rating range, with no resulting damage. However, the employment of electronic components such as e.g. MOSFETs or IGBTs is also possible. This is particularly appropriate, in the event that the electrical energy source generates DC voltages.

According to a preferred configuration of the invention, the method comprises the following steps: a current intensity and/or a voltage is measured in at least one of the phase conductor current paths. Measured values are transmitted to a control unit of the switch device. The control unit transmits control commands to the switching elements and short-circuiting switches on the basis of measured values which are measured in the phase conductor current paths.

According to a preferred configuration of the invention, the method comprises the following step: switching elements are switched to a non-conducting state, in the event of the occurrence of an overcurrent, such as e.g. a short-circuit current, in a phase conductor current path, or in the event that the execution of a regulation switch-off of the load is intended.

According to a preferred configuration of the invention, the method comprises the following step: by means of one or more of the short-circuiting switches, the n phase conductor outputs of the switch device are connected in an electrically conductive manner to a (n+1)^{th} input, which input is appropriate for electrically connecting to a ground conductor or neutral conductor of the energy source.

According to a preferred configuration of the invention, the method comprises the following step: from each of the above-mentioned n phase conductor outputs, by means of a respective short-circuiting switch, an electrical connection is established with the (n+1)^{th} input of the switch device, which input is appropriate for electrically connecting to a ground conductor or neutral conductor of the energy source.

According to a preferred configuration of the invention, the method comprises the following step: by means of a 15(n+1 )^{th} current path within the switch device, the (n+1)^{th} input of the switch device, which input is appropriate for electrically connecting to a ground conductor or a neutral conductor of the energy source, is electrically connected to a (n+1)^{th} output of the switch device, which output is appropriate for electrically connecting to a ground conductor or a neutral conductor of the load, thus forming a ground or neutral conductor connection within the switch device.

According to a preferred configuration of the invention, the switching elements are electronic components. This is advantageous, on the grounds that electronic components can be switched on in a significantly temporally more rapid and more accurate manner than mechanical switching elements. The time interval between the assumption of a zero value by switching element currents and the switch-on of short-circuiters can thus be minimized, and the time during which overvoltage limiting elements are thermally loaded thus additionally reduced. Short-circuiting switches are electronic switches which execute the function of an electromechanical switch, but which comprise no moving parts. Short-circuiting switches are switchable to a high-ohmic state, for preventing a current flux, or to a low-ohmic state, for enabling a current flux in a current path; to this end, semiconductor-based switching elements such as field-effect transistors (FETs), MOSFETs (e.g. based upon silicon, gallium nitride, or silicon carbide), IGBTs, bipolar transistors or diodes can be employed. An electronic switching element, additionally to a semiconductor switch, can comprise a protective element for the semiconductor switch.

According to a preferred configuration of the invention, switching elements are electronic components of the MOSFET (metal oxide semiconductor field-effect transistor) or IGBT (insulated-gate bipolar transistor) type. Electronic components, such as e.g. MOSFETs or IGBTs, are appropriate by way of electronic components for switching elements.

According to a preferred configuration of the invention, the electrical energy source comprises one or more voltage sources for generating an AC voltage. According to a preferred configuration of the invention, the electrical energy source comprises voltage sources for generating a DC voltage. The present invention functions both with a DC voltage and an AC voltage. The preference for an AC or DC voltage is determined according to the option which is more appropriate for the relevant application.

According to a preferred configuration of the invention, short-circuiting switches remain in a switched-on state during the period further to the switch-off of switching elements and pending the time of the next switch-on of switching elements. As a result, induced overvoltages in the load circuit, e.g. associated with other spatially proximal current circuits or associated with an indirect effect of lightning stroke, can be withheld from the semiconductor switches and the switch device.

The invention is described hereinafter with reference to the attached drawing. In each case, in a schematic and non-true-to-scale manner:

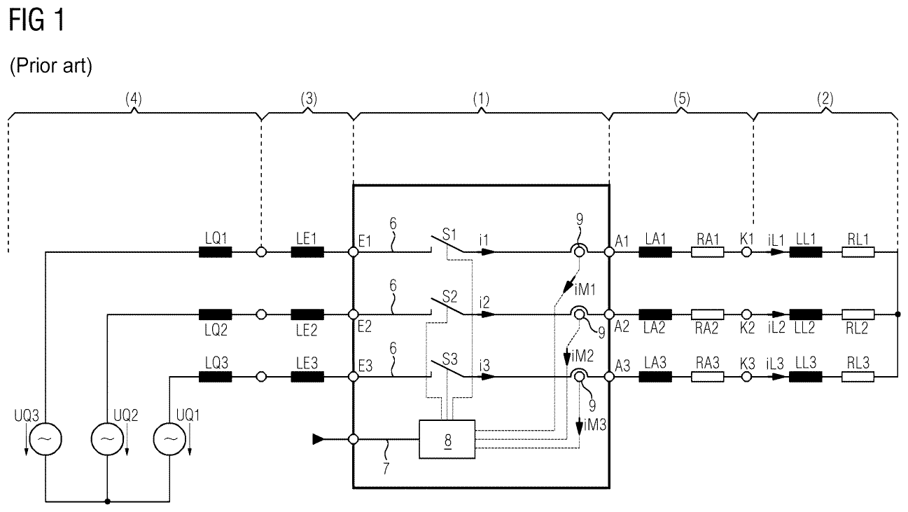

FIG. 1 shows a conventional switch device;

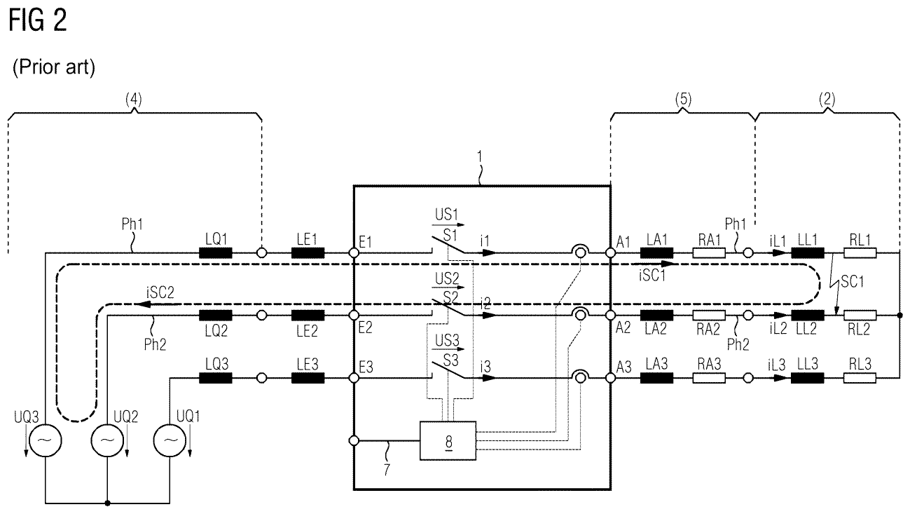

FIG. 2 shows the conventional switch device according to FIG. 1, having a short-circuit within the load, between two electrical phases;

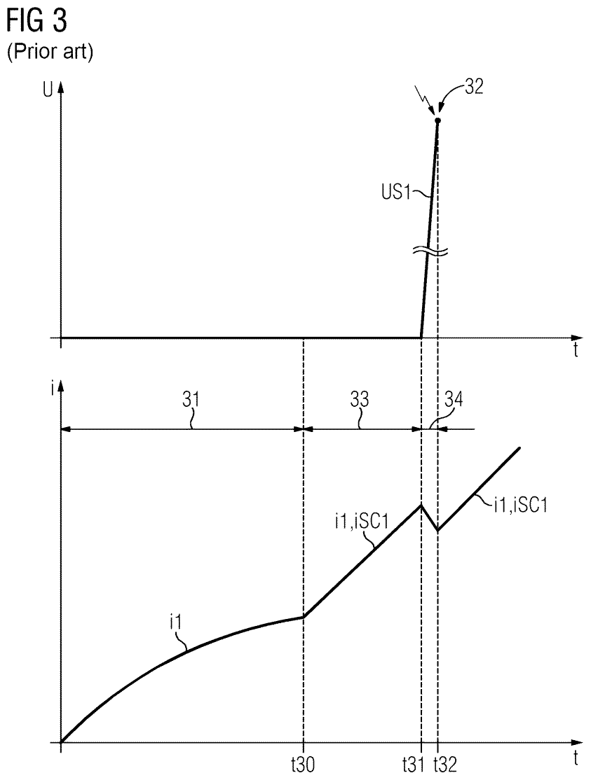

FIG. 3 shows current and voltage characteristics in the event of a short-circuit according to FIG. 2;

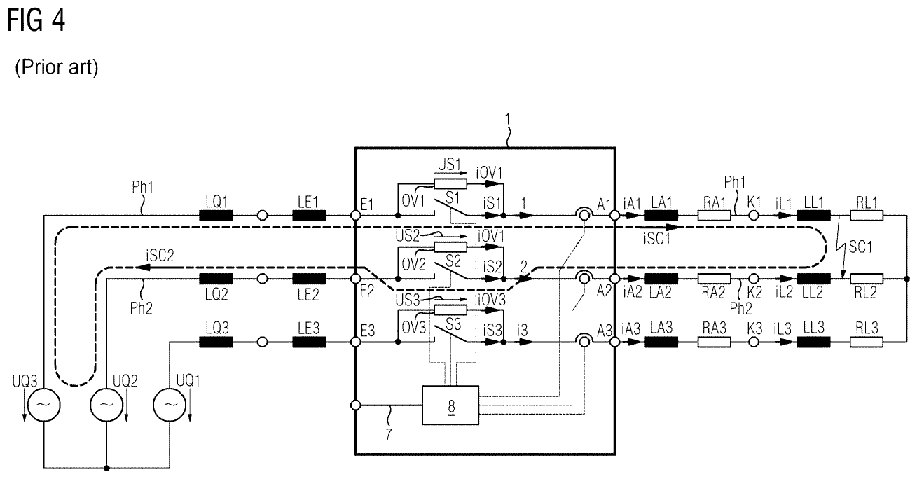

FIG. 4 shows a conventional switch device having overvoltage limiting elements arranged above the switching elements, wherein a short-circuit occurs within the load between two electrical phases;

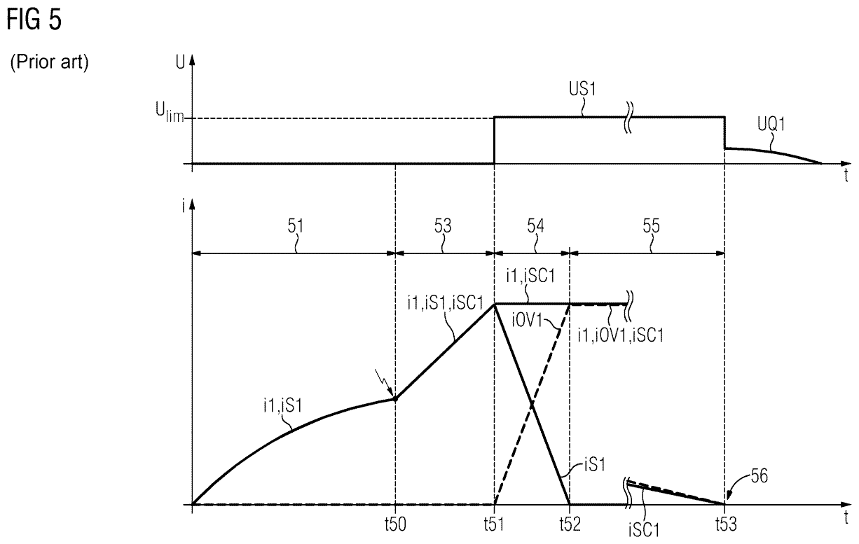

FIG. 5 shows current and voltage characteristics in the event of the short-circuit according to FIG. 4;

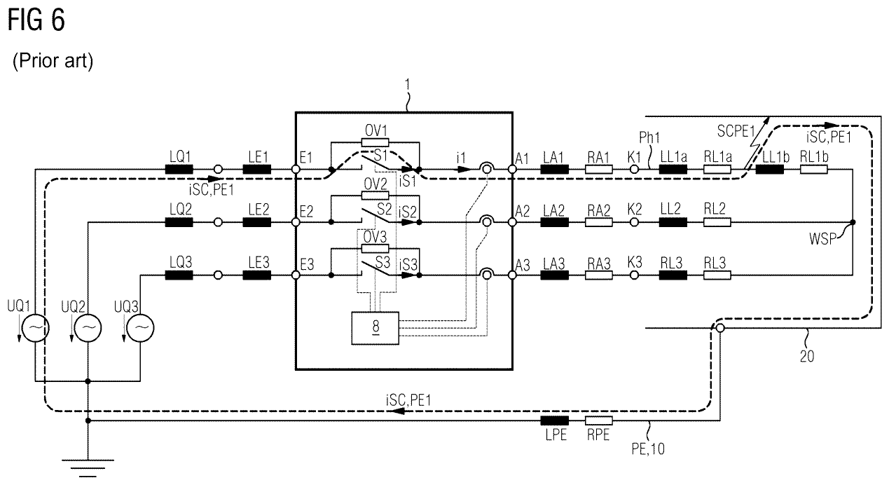

FIG. 6 shows a conventional switch device having overvoltage limiting elements arranged above the switching elements, wherein a ground fault occurs within the load between one electrical phase and a metallic housing of the load;

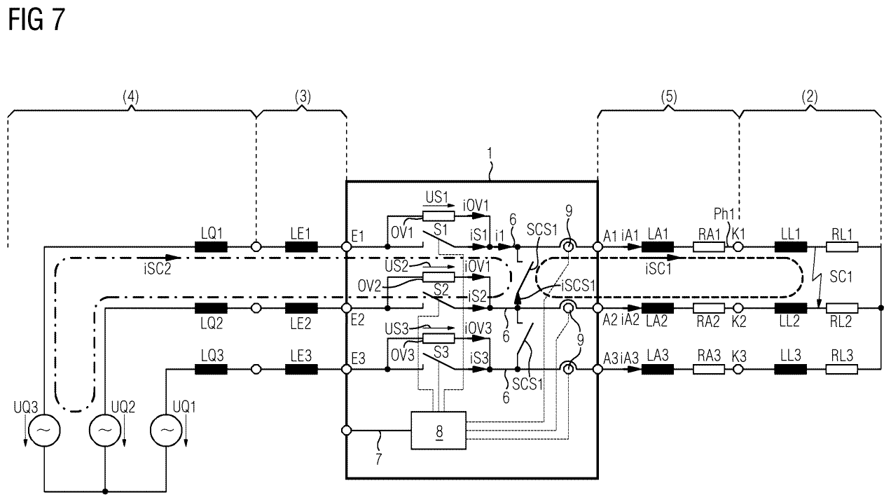

FIG. 7 shows a switch device according to the invention having two internal short-circuiters, wherein a short-circuit occurs within the load between two electrical phases ;

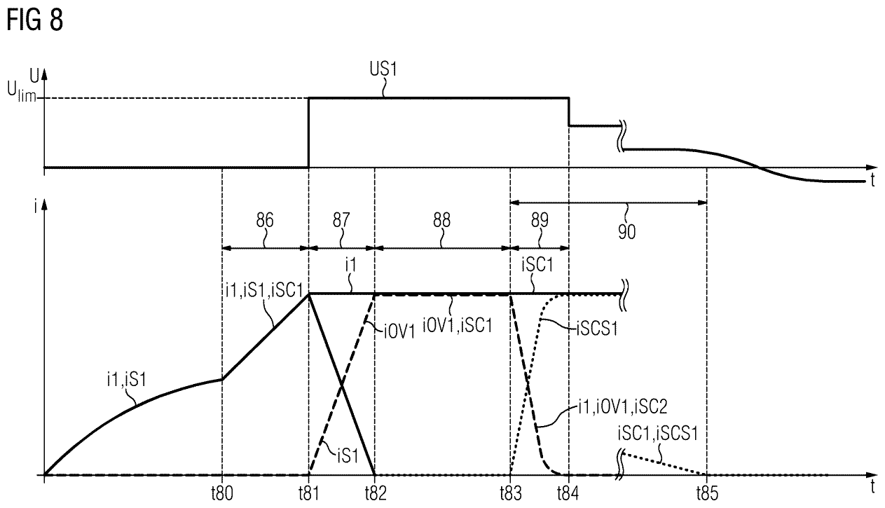

FIG. 8 shows current and voltage characteristics in the event of the short-circuit according to FIG. 7;

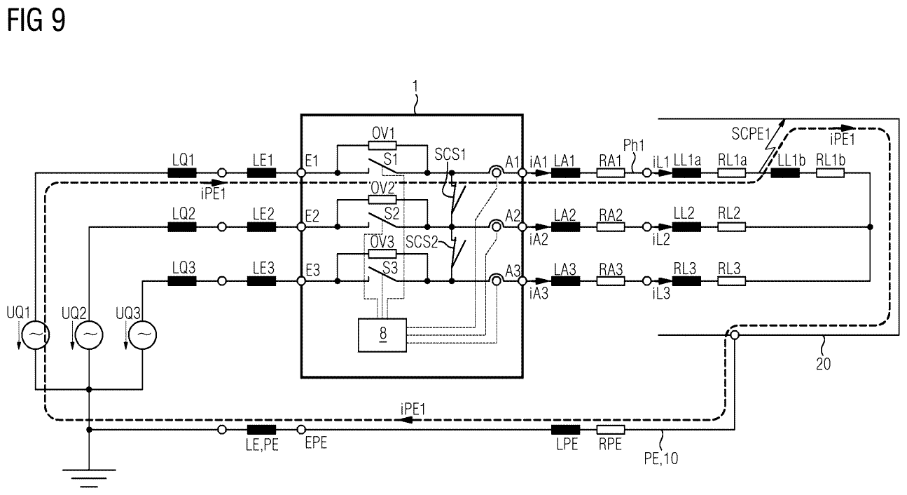

FIG. 9 shows a switch device according to the invention having two internal short-circuiters, wherein a ground fault occurs;

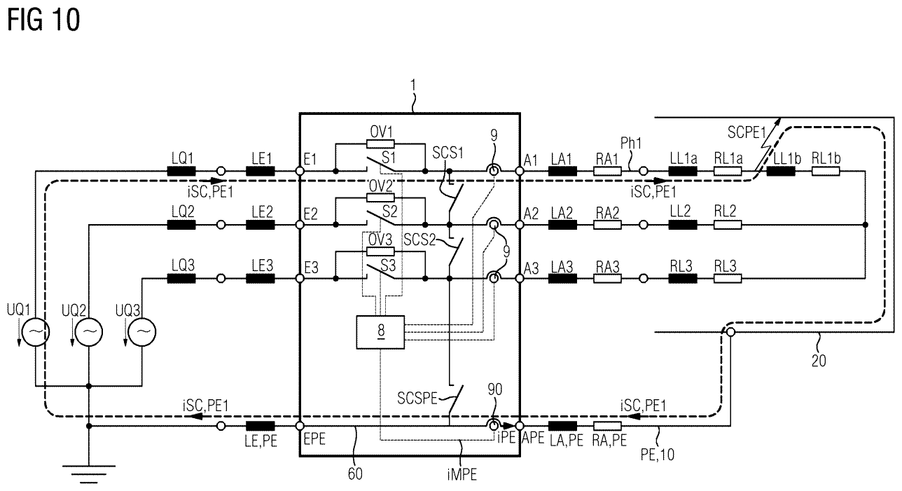

FIG. 10 shows a switch device according to the invention having three internal short-circuiters, one of which is connectable to a ground conductor;

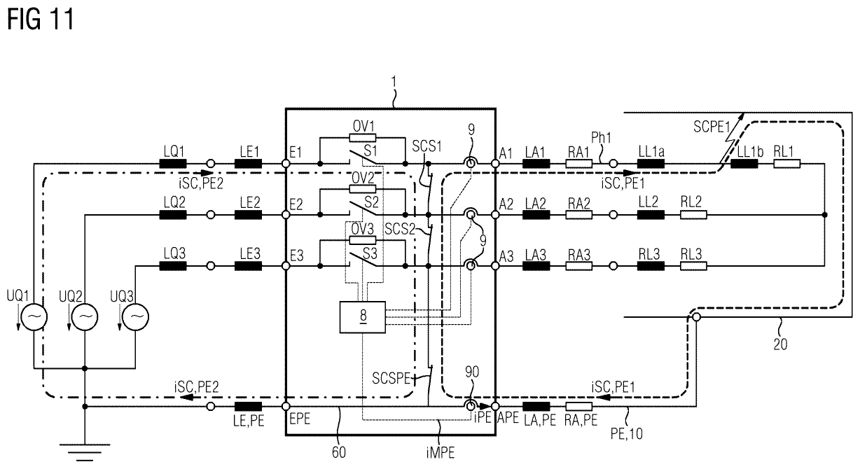

FIG. 11 shows the switch device according to the invention, according to FIG. 10, wherein ground fault current paths further to the closing of the three internal short-circuiters are illustrated;

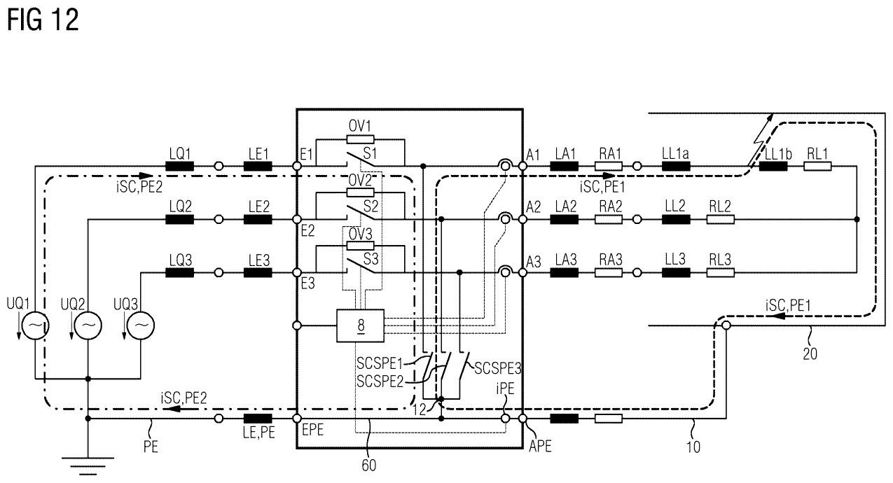

FIG. 12 shows a switch device according to the invention having three internal short-circuiters, each of which can respectively short-circuit an output of a current path to the ground conductor;

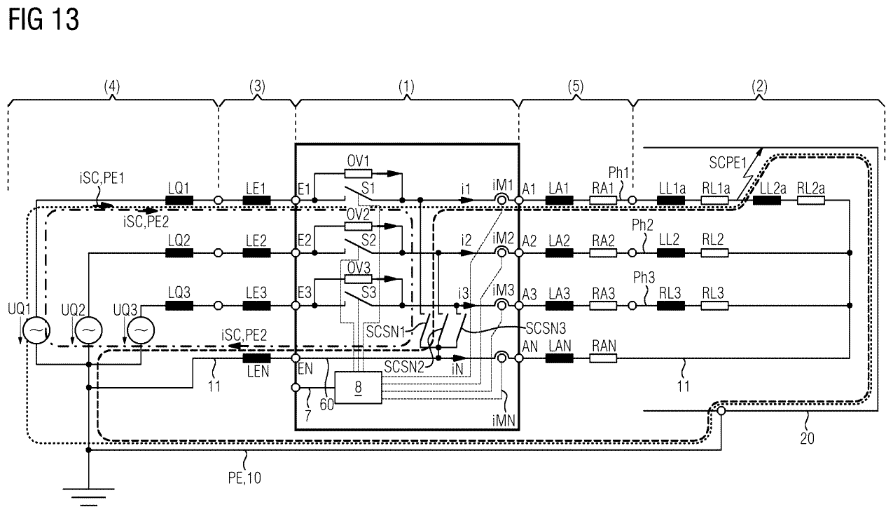

FIG. 13 shows a switch device according to the invention having three internal short-circuiters, each of which can respectively short-circuit an output of a current path to a neutral conductor;

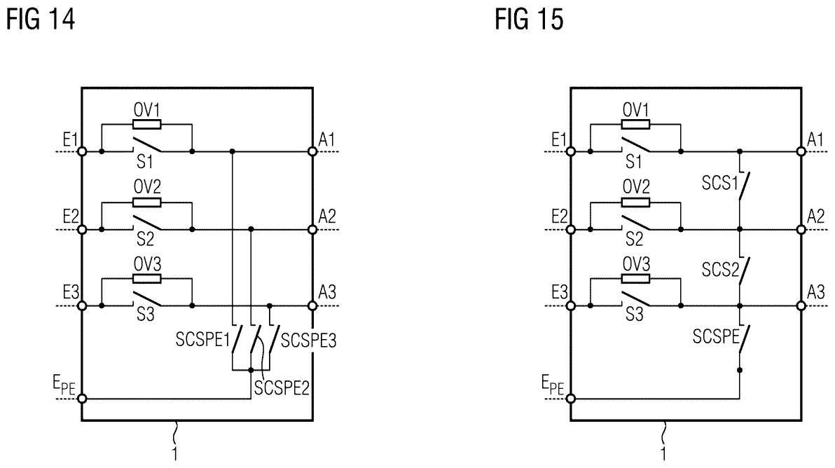

FIG. 14 shows a switch device according to the invention having three internal short-circuiters, each of which can respectively short-circuit a phase conductor output of a phase conductor current path with an input to a ground conductor;

FIG. 15 shows a switch device according to the invention having three internal short-circuiters, two of which can mutually short-circuit two phase conductor current paths, and the third short-circuiter of which can short-circuit a phase conductor current path with an input to a ground conductor; and

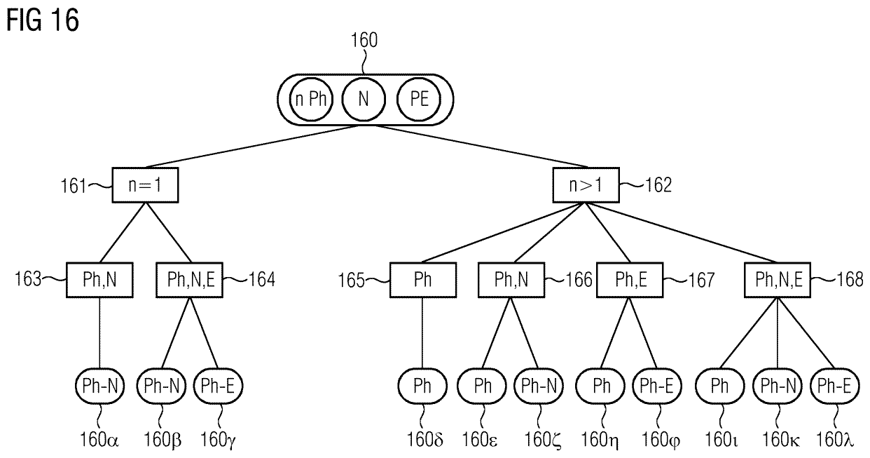

FIG. 16 shows a structural diagram presenting an overview of various configurations of the conductor system.

FIG. 1 shows an electrical switch device 1. Electrical switch devices are employed for connecting electrical loads to the electric power grid, and for the controlled supply of electrical energy thereto.

To this end, the switch device 1 comprises input terminals E1, E2, E3 to which input connection lines 3, which lines connect an electrical energy source 4, in the present case, an exemplary three-phase AC system having phase voltages UQ1, UQ2, UQ3, to the switch device 1. At output terminals A1, A2, A3 of the switch device 1, load connection lines 5 are connected, which lines are routed to a load 2 and are 20 connected therein to load connection terminals K1, K2, K3, such that the load 2 is electrically connected to the switch device 1.

Within the switch device 1, each of the inputs E1, E2, E3 is routed via an electric current path 6 to exactly one of the outputs A1, A2, A3 wherein, customarily, the first input E1 is routed to the first output A1, the second input E2 is routed to the second output A2, and the third input E3 is routed to the third output A3. Via each current path 6, electric current is conducted from an input E1, E2, E3 to a corresponding output A1, A2, A3, such that electrical energy is conducted from the electrical energy source to the load 2.

Within each current path 6, an electrical switching element S1, S2, S3 is located, e.g. in the current path 6 from the first input E1 to the first output A1, a first switching element S1. By means of the electrical switching elements S1, S2, S3, electric currents i1, i2, i3 flowing in the current paths 6 are controlled, in order to supply the load with the requisite electrical energy at stipulated times. For the control of current by means of the switching elements S1, S2, S3, the switch device 1 comprises a control input 7 which is connected to a control unit 8 of the switch device 1 in an electrically conductive manner. The control unit 8 assumes the targeted control of the electrical switching elements S1, S2, S3, in order to execute the appropriate supply of energy to the load 2. Additionally to the control input 7, further electrical variables, such as e.g. currents iM1, iM2, iM3 in the current paths 6 measured by means of sensors 9, in particular by current measurement devices, can be routed to the control unit 8, such that the control unit 8 can execute additional functions, such as e.g. an overload protection of the load 2.

In many cases, electrical switching elements S1, S2, S3 are embodied as mechanical switching contacts, by means of which a simple switch-on and switch-off of the load 2 is enabled. By the employment of state-of-the-art electronic power components, such as e.g. MOSFET transistors based upon silicon carbide, electronic switching elements can be produced which enable a very rapid switch-on and switch-off of electric current. This rapid switching capacity can be employed for the interruption of a rapidly rising current in output-side current circuits which results, e.g. from a short-circuit. Energy thus converted is lower by some orders of magnitude than that associated with mechanical switch devices, such that any destruction occurring at the location of a short-circuit is substantially reduced.

A very rapidly rising current occurs, e.g. in the event of a short-circuit between the load connection lines or in the load 2. In FIG. 2, by way of an example, a short-circuit SC1 is illustrated within the load 2. A short-circuit current iSC1 is formed in the first electrical phase Ph1 and in the second electrical phase Ph2, represented in FIG. by a broken line, which current flows through the two input connection lines 3, the two load connection lines 5, elements of the load 2 and the AC voltage sources UQ1 and UQ2 of the electrical energy source 4.

FIG. 3, for the occurrence of a short-circuit, represents the temporal characteristic of the voltage uS1 across the switching element S1 (upper part of the diagram in FIGS. 3), and of the current i1 in the first electrical phase Ph1 (lower part of the diagram in FIG. 3). Time intervals are not represented true-to-scale. Proceeding from a current flux in normal operation 31 (t<t30), in which the switching element S1 carries the current i1, at a time point t30, a short-circuit SC1 occurs: t30=time at which the short circuit commences. The current i1 becomes the short-circuit current iSC1 and, during the time interval 33, rises very rapidly until, at time point t31, within a few microseconds, the detection thereof occurs, and the short-circuit interruption process is initiated. The interruption process is initiated by the switch-off of the electronic switching elements S1 and S2 at time point t31: t31=time of interruption. The current i1 flowing through the switching element S1 or the current i2 flowing though the switching element S2 commences to fall very rapidly such that, within a very short time, typically between and 200 nanoseconds, a fall thereof to a zero value would occur.

As a result of the very rapid variation of current i1, which is equal to the short-circuit current iSC1, very high voltages US1 are formed on the inductances of the short-circuit current circuit, LQ1, LE1, LA1, LL1 and LQ2, LE2, LA2, LL2, which voltages are then manifested on the current-interrupting switching elements S1 and S2 in the form of a very high voltage stress such that, within a very short time, at time point t32, a destruction 32 of the electronic switching elements S1 and S2 occurs: t32=time point of overvoltage-related defect of switching element. In many cases, switching elements are of a very low-ohmic design, such that the short-circuit current iSC1 commences to rise again in time interval 34.

A further operational situation involving a high voltage stress on electronic switching elements can occur in the event of a normal switch-off of an asynchronous motor. The asynchronous motor, further to the switch-off thereof, for a short time interval ranging from 100 milliseconds up to several seconds, generates sinusoidal electric voltages at the output terminals thereof, which voltages are comparable to the those of the three-phase AC voltage grid by means of which the asynchronous motor is supplied.

At the start of this time interval, the magnitude of sinusoidal output terminal voltages almost achieves the magnitude of sinusoidal voltages on the three-phase AC voltage grid and, at the end of this time interval, decays to zero. The frequency of motor terminal voltages varies in a proportional manner to the speed of rotation of the rotor of the asynchronous motor, and decays gradually, in accordance with the loading of the motor. In the event of a rapid variation of the rotor speed, and thus of the frequency of motor terminal voltages, sinusoidal motor terminal voltages, further to a few line periods, assume a phase opposition to sinusoidal voltages on the three-phase AC grid, i.e. the maximum voltage values of the motor terminal voltages coincide with minimum voltage values on the three-phase AC grid, and vice versa. For electronic switching elements in a switched-off state, in the short term, this signifies a near-doubling of voltage stress.

In the event of the rapid switching of currents i1, i2, i3, as a result of inductances in current circuits, a very high voltage stress occurs in the electronic switching elements S1, S2, S3, as a result of which, in the absence of appropriate protective measures, the latter would be destroyed.

FIG. 4 represents a solution which has thus been developed wherein, for the protection of electronic switching elements S1, S2, S3, overvoltage elements OV1, OV2, OV3 are arranged in parallel with the electronic switching elements S1, S2, S3, namely, overvoltage limiting element OV1 is arranged in parallel with switching element S1, overvoltage limiting element OV2 in parallel with switching element S2, and overvoltage limiting element OV3 in parallel with switching element S3.

The overvoltage limiting action associated with the over-voltage limiting elements OV1, OV2 and OV3 is generated wherein the latter, in excess of a specific voltage value US1, US2, US3, which value is described as the voltage limiting value, assume a conducting state, and conduct the currents iOV1 iOV2, iOV3, such that any further voltage rise thereon is relatively restricted. The voltage limiting value US1, US2, US3 is selected such that the maximum permissible voltage of the electronic switching elements S1, S2, S3 is not exceeded during the voltage limiting process.

FIG. 5 illustrates temporal correlations associated with a switch-off operation, wherein for switching element S1, as an exemplary current which is to be interrupted, a short-circuit current SC1 within the load 2 is assumed, as represented in FIG. 4.

Proceeding from a current flux in normal operation 51 (t<t50), in which the switching element S1 carries the current i1, at a time point t50, a short-circuit SC1 occurs: t50=time at which the short-circuit commences. The current i1 becomes the short-circuit current iSC1 and, during the time interval 53, rises very rapidly until, at time point t51, within a few microseconds, the detection thereof occurs, and the short-circuit interruption process is initiated. The interruption process is initiated by the switch-off of the electronic switching elements S1 and S2 at time point t51: t51=time of interruption. The current iS1 flowing through the switching element S1 commences to fall very rapidly such that, within a very short time interval 54, typically between and 200 nanoseconds, a fall thereof to a zero value would occur.

As the rate of current decay of the switching element currents iS1 and iS2 upon the interruption thereof is sufficiently high such that a voltage u far in excess of the voltage limiting value uₗᵢₘ of the voltage limiting elements OV1 and OV2 would be generated on inductances in the short-circuit current circuit, the overvoltage limiting elements OV1 and OV2 are active almost immediately further to the commencement of the decay of the currents iS1 and iS2 at time point t51, and limit the voltage uS1 and uS2 on the electronic switches S1 and S2 to the voltage limiting value uₗᵢₘ. The voltage characteristic across the switching element S1 is represented in the upper part of the diagram in FIG. 5. The overvoltage limiting elements OV1 and OV2 carry a current iOV1 or iOV2 which is equal to the difference between the short-circuit current iSC1 and the rapidly decaying current iS1 flowing through the first switching element S1 or the current iS2 flowing through the second switching element S2.

If the switching element currents iS1 and iS2 have assumed a zero value at time point t52, the short-circuit current iSC1, in the time interval 55, which can range from several hundred microseconds up to a few milliseconds, flows entirely via the voltage limiting elements OV1 and OV2. During the switch-off of the switching elements S1, S2, a switchover of the short-circuit current iSC1 is thus executed from the first switching element S1 to the parallel-connected overvoltage limiting element OV1, and from the second switching element S2 to the parallel-connected over-voltage limiting element OV2.

Subsequently, the short-circuit current iSC1 then decays to the extent that the magnetic energy of inductances of the short-circuit current circuit, in the ohmic resistances of the short-circuit current circuit and in the overvoltage limiting elements OV1, OV2, is converted into heat. The magnetic energy E_{mag} present in the inductances is proportional to the quadratic current which flows therein.

If magnetic energy in the inductances is entirely converted into heat, the short-circuit iSC1 at time point t53 will have decayed to zero, and the short-circuit process is thus terminated 56. No further current flows from the electrical energy source to the load 2, and the switch device 1 has interrupted the current flux.

On the electronic switching elements S1, S2, S3, a voltage is now applied which is dictated by the voltage sources UQ1, UQ2 and UQ3 of the electrical energy source 4.

It is necessary for the overvoltage limiting elements OV1 and OV2 to be dimensioned such that they are capable of the full conversion of the magnetic energy of inductances LQ1, LE1, LA1, LL1 and LQ2, LE2, LA2, LL2, which are present in the short-current circuit, into heat, without sustaining damage. Energy which is converted into heat in the ohmic resistances RA1, RL1, RA2, RL2, in comparison with energy which is converted in the overvoltage limiting elements OV1 and OV2, is negligibly small, and can thus be ignored.

The dimensioning of the overvoltage limiting elements OV1 and OV2 is critical, in that this dimensioning is dependent upon the magnitude of inductances in the entire electrical assembly, and is thus dependent upon multiple parameters. Whereas inductances LQ1 and LQ2 of the electrical energy source can be estimated in a relatively simple manner, inductances of the input connection lines, which are proportional to the line length thereof, generate a first variable, as a result of the unknown line length. For the purposes of simplification, however, it can be assumed that electrical distribution facilities in which switch devices are installed are generally located in proximity to the electrical energy source, such that the resulting line lengths are typically short: typical values for line lengths lie within the range of 3 to 30 m. On the output side of the switch device 1, towards the load 2, the potential range of values within which inductances can lie increases significantly. Firstly, the length of load connection lines can vary from a few meters up to several hundred meters. Secondly, the load 2 itself can assume a significantly differing inductive behavior, such that e.g. an asynchronous motor has an inductive component which is dependent upon the operating state thereof and, namely, is greater during the run-up phase than in rated operation. Conversely, for example, heating elements assume a predominantly ohmic character, with only a limited inductive component.

For the dimensioning of overvoltage limiting elements, it is necessary for realistic lengths of load connection lines and load properties to be defined. Thereafter, these parameters must also be described in operating instructions for the device.

One variant of the short-circuit according to FIG. 2 is a ground fault, which represents an electrically conductive connection between an electrical element of the current circuit and a grounded electrical conductor, wherein this connection, in the majority of cases, results from an insulation defect of an electrical element.

FIG. 6 shows an exemplary ground fault. In this case, the ground fault SCPE1 occurs in the first electrical phase Ph1 within the load 2, the electrical behavior of which is described by the series-connected arrangement of a resistance and an inductance; this series-connected arrangement can be embodied, e.g. by a motor winding. As a result of an insulation defect, a transfer of current occurs to the iron plates of the motor, which plates are connected, in an electrically conductive manner, to the grounded motor housing 20. A ground fault current circuit is formed, as represented by a broken line, having the ground fault current iSCPE1, which current flows through the electrical components of the first electrical phase Ph1, the metallic motor housing 20 and a ground conductor PE 10 (PE=protective earth).

The position of the insulation defect within the motor winding thus assumes a strong influence upon the characteristic and the magnitude of the ground fault current iSCPE1. If the insulation defect is located in proximity to the load connection terminal K1, the winding inductance L_{L1A} and the winding resistance R_{L1A} are small, such that the ground fault current iSCPE1 can rapidly assume very high values. However, if the insulation fault is located in proximity to the winding star point WSP of the motor, the winding inductance L_{L1A} and the winding resistance R_{L1A} are almost as high as in the absence of a fault. The ground fault current iSCPE1 thus formed will then be low. Depending upon the location of the insulation defect, all intermediate stages of ground fault current development between these two extremes will be possible.

This variability of the magnitude of the ground fault current and of the effective inductance LLia which, in combination, critically influence the magnetic energy of the ground fault current circuit, must be taken into consideration in the dimensioning of overvoltage limiting elements, as magnetic energy is essentially converted into heat therein. The difficulty here is the identification of the least favorable case, in order to enable an appropriate design rating of overvoltage limiting elements.

The issue of high voltage stress on electronic switching elements during the normal switch-off of an asynchronous motor, associated with the superimposition of voltages on the three-phase AC grid upon the motor terminal voltages, is resolved by a sufficiently high dielectric withstand of switching elements. To this end, it is necessary for switching elements to be rated for approximately double the voltage value which, in the least favorable case, can occur in the normal operation of the three-phase AC grid by way of a maximum value.

In summary, it can be observed that the issue outlined hereinafter exists: switch devices having semiconductor-based switching elements, which elements can interrupt electric currents relatively rapidly, are required to interrupt currents in the event of a fault, e.g. in case of short-circuits. During an interruption process of this type, high overvoltages are generated on switching elements, the restriction of which to non-hazardous values by means of overvoltage limiting elements is required. Over-voltages are caused by inductances which are present in current circuits. At the time of interruption, magnetic energy which is stored in inductances, during the interruption process, must essentially be assumed by the overvolt age limiting elements and converted into heat, with no resulting overload of the latter. The design rating of over voltage limiting elements is thus primarily dependent upon the magnitude of inductance values and of currents which are to be interrupted in current circuits. Inductance values and the magnitude of currents which are to be interrupted are strongly dependent upon the length of load connection lines, the type of load, and the reason for switch-off.

One issue arises, in that it is necessary for appropriate assumptions of the length of load connection lines and of the type of load to be adopted, and for the least favorable switch-off events to be identified, in order to enable the dimensioning of overvoltage limiting elements to an acceptable magnitude. The length of load connection lines and load types must then be incorporated as terms which are defined in operating instructions. With respect to short-circuit or switch-off events, there is a relatively limited residual risk to the effect that the least favorable case will not be considered, such that the occurrence of device defects is possible in the field. In the case of mechanical switch devices, on the grounds of the high robustness thereof, the definition of such above-mentioned terms in operating instructions is not necessary.

A further problem for the dimensioning of overvoltage limiting elements is posed by the normal switch-off of an asynchronous motor wherein, by the interaction of load output terminal voltages and voltages on the three-phase AC grid, increased voltages occur on switching elements which, although not resulting in the damage thereof, can generate a response of overvoltage limiting elements, on the grounds of the necessity that the voltage limiting value thereof is lower than the maximum permissible switching element voltage. This is attributable to tolerances in overvoltage limiting elements, and the non-ideal limiting function thereof.

It is necessary for the limiting value to be selected such that, at a position thereof in the lower tolerance band, overvoltage limiting elements, further to a switch-off, do not respond, or at least do not respond to an excessive degree and thus undergo heat-up whereas, at the same time, at a position thereof in the upper tolerance band, even at the maximum anticipated switch-off current value, the voltage on switching elements is limited to acceptable values. In practice, on the grounds of wide tolerance bands and the non-ideal limiting characteristic, establishment of the voltage limiting value of overvoltage limiting elements is not simple, and is further exacerbated by the temperature-dependence of the voltage limiting value, such that the preferred limiting value frequently represents a compromise which incorporates some gray areas, within which the limiting function operates in a sub-optimal manner only.

FIG. 7 represents the principle for the solution of this problem, upon which the present invention is based. In the switch device 1, short-circuiting switching elements SCS1 and SCS2 are installed between the switching elements S1, S2, S3 and the output terminals A1, A2, A3. These short circuiting switching elements can also be described as “short-circuiting switches”, or simply as “short-circuiters”. The short-circuiter SCS1 can short-circuit the two output terminals A1 and A2, or the two switching elements S1 and S2, and the short-circuiter SCS2 can short-circuit the output terminals A2 and A3 or the two switching elements S2 and S3.

By way of illustration of the mode of operation, in FIGS. 7, an unintentional short-circuit SC1 within the load 2, be tween the first electrical phase Ph1 and the second electrical phase Ph2, is assumed. Pending the detection of the short-circuit SC1 and the initiation of a current interruption, the short-circuit current iSC1 is formed, as represented in FIG. 7 by a broken line. In FIG. 8, which represents the temporal characteristics of currents (lower part of the diagram in FIG. 8) and voltage (upper part of the diagram in FIG. 8) for the switching element S1 and the overvoltage limiting element OV1, the time interval 86 between t80, the commencement of the short-circuit, and t81, the commencement of interruption, is typically of a few microseconds in duration.

Further to the switch-off of the switching elements S1 and S2 at time point t81 in FIG. 8, the currents iS1 and iS2 decay very rapidly; however, as a result of the inductances L1, LE1, LA1, LL1 and LQ2, LE2, LA2, LL2, the voltage uS1, uS2 on the switching elements S1, S2 rises very rapidly, up to the voltage limiting value uₗᵢₘ of the overvoltage limiting elements OV1 and OV2. At time point t82, which occurs at a time interval 87 of typically to 200 nanoseconds further to the time point t81 of the commencement of interruption, the currents iS1 and iS2 have decayed to a zero value.

At time point t83, which occurs at a relatively short time interval 88, typically of to 50 microseconds further to the time point t82, the short-circuiter SCS1 is switched on. As represented in FIG. 7, two current circuits are formed: a first, load-side current circuit, wherein the current iSC1 flows through the load connection lines 5, an element of the load 2 and the short-circuiter SCS1; and a second, source-side current circuit, wherein the current iSC2 flows the input connection lines 3, the electrical energy source 4, the two overvoltage limiting elements OV1 and OV2 and, as per the first current circuit, through the short-circuiter SCS1. The term “load-side” signifies an object, such as e.g. an electrical element or an electrical phenomenon such as, e.g. a current flux which, with respect to the switch device 1, is located closer to the load 2 than to the current source 4, whereas the term “source-side” signifies a location which is closer to the current source than to the load 2.

The source-side current iSC2 thus decays substantially more rapidly than the load-side current iSC1, as the magnetic energy of inductances of the input connection lines 3 and of the electrical energy source is rapidly converted into heat in the overvoltage limiting elements OV1 and OV2, whereas the magnetic energy of the load connection lines 5, and of the inductance of the load 2 which was in force prior to the occurrence of the short-circuit, is only slowly converted into heat in the low-ohmic resistances RA1, RA2.

The source-side current iSC2, as per the current iOV1 flowing through the first overvoltage limiting element OV1 and the current i1 flowing through the first current path 6, assumes a zero value at time point t84, whereas the load-side current iSC1 only decays to zero at time point t85. 20 The time interval 89 between time point t83, at which the short-circuiter SCS1 is switched to an electrically conducting state, and time point t84, at which the source-side current iSC2 has decayed to zero, typically lies within the range of several hundred milliseconds, whereas the corresponding time interval 90, in the case of the load-side current iSC1, can be up to several hundred milliseconds in duration.

For such time as the source-side current iSC2 flows, heat is generated thereby in the overvoltage limiting elements OV1, OV2. In comparison with a switch-off in the absence of short-circuiters, as represented in FIG. 4, however, the duration of the current flux in the overvoltage limiting elements OV1, OV2 is substantially shorter, as only the decay of the magnetic energy of inductances of the input connection lines 3 and of the electrical energy source is required. The conversion into heat by the overvoltage limiting elements OV1, OV2 of magnetic energies on the load side which, depending upon the line length and load type, can be very high in value, is no longer required. The over-voltage limiting elements OV1, OV2 can thus be dimensioned with a substantially lower rating, as only the rating thereof for the comparatively low inductances of the input connection lines 3 and of the electric voltage source is required.

The operating principle of the invention has been described, with reference to FIG. 7, in the case of a short-circuit within the load 2 between the first electrical phase Ph1 and the second electrical phase Ph2, without addressing the third electrical phase Ph3 in greater detail. Given that, in the non-defective third electrical phase Ph3, the current which was in force in normal operation, prior to the short-circuit, will continue to flow, the third switching element S3, together with the two other switching elements S1 and S2, is switched off and, together with the short-circuiter SCS1 for outputs A1 and A2, the short-circuiter SCS2 for outputs A2 and A3 is also activated, as the output current iA3 which flows in the third current path from the third output A3 in the direction of the load 2 would otherwise flow back to the energy source 4 via the first and second electrical phases Ph1 and Ph2, such that not only the third overvoltage limiting element OV3 of the third switching element S3, but also the two other overvoltage limiting elements OV1 and OV2 would additionally undergo heat-up.

As a result of the simultaneous switch-off of all three switching elements S1, S2, S3 and the simultaneous switch-on of the two short-circuiters SCS1 and SCS2, the same mode of operation applies to all other unintentional short-circuits which might potentially occur between any other two arbitrary electrical phases; even in the event of a simultaneous short-circuit on all three electrical phases, the load-relief function of the overvoltage limiting elements OV1, OV2, OV3 is maintained.

The short-circuiting switches SCS1 and SCS2 are preferably manufactured using electronic components, as these components can be switched on in a significantly temporally more rapid and more accurate manner than mechanical switching elements. The time interval between the assumption of a zero value by switching element currents iS1, iS2, iS3 and the switch-on of the short-circuiters SCS1 and SCS2 can thus be minimized, and the time during which overvoltage limiting elements OV1, OV2, OV3 are thermally loaded thus additionally reduced. By way of electronic components for short-circuiting switches, thyristors and TRIACs are particularly appropriate in the event that the electrical energy source generates an AC voltage, as thyristors and TRIACs spontaneously interrupt the current flux, once the current has fallen below a specific threshold. Moreover, these components assume a high short-term current loading capability; as a result, maximum short-circuit current values occurring in the range of 300 to 600 A can be conducted using cost-effective components in a lower rating range, with no resulting damage. However, the employment of electronic components such as e.g. MOSFETs or IGBTs is also possible. This is particularly appropriate, in the event that the electrical energy source generates a DC voltage.

In addition to the function for the load relief of over voltage limiting elements OV1, OV2, OV3 upon the switch-off of a current in the load circuit, the short-circuiters SCS1 and SCS2 can also be switched-in further to a normal switch-off operation, immediately the output currents iA1, iA2, iA3, i.e. the currents routed from the output terminals A1, A2, A3 of the switch device 1 to the load 2, assume a zero value.

By the short-circuiting of the load connection terminals K1, K2, K3 further to a switch-off, any perturbations of the switch device 1 by the load 2 are prevented. In the case of an asynchronous motor, these perturbations take the form of voltages at the output terminals A1, A2, A3 thereof, such that an increased voltage stress of the switching elements S1, S2, S3 associated with the motor 2 can no longer occur. As a result, electronic switching elements having a lower off-state voltage can be preferred and, at the same time, issues associated with the selection of the voltage limiting value Uₗᵢₘ of the overvoltage limiting elements OV1, OV2, OV3 can be attenuated.

The solution represented in FIG. 7 for the load-relief of overvoltage limiting elements OV1, OV2, OV3 by means of the two short-circuiters SCS1 and SCS2 functions for all short-circuits between the electrical phases Ph1, Ph2, Ph3. In the event that the short-circuit is a ground fault, and occurs between one or more electrical phases and a grounded conductor PE, 10, however, short-circuiting by means of the short-circuiters SCS1 and SCS2 will not function.

For the purposes of illustration, FIG. 9 shows the ground fault SCPE1 in the first electrical phase Ph1 within the 31 load 2, vis-à-vis the grounded housing 20 of the load 2.

The ground fault current iPE1, represented by the broken line, is formed, which current flows via the grounded housing 20 of the load 2, the ground conductor PE, 10, the voltage source uQ1 and the first switching element S1 back to the location of the ground fault SCPE 1. In this case, the above-mentioned interruption sequence for a short-circuit has no impact upon the ground fault current iPE1, as the ground fault current iPE1 flows via the ground conductor PE, 10, and thus bypasses the short-circuiters SCS1 and SCS2. The overvoltage limiting element OV1 is loaded to a level which is comparable to that associated with an absence of short-circuiters. Accordingly, a smaller dimensioning of the overvoltage limiting elements OV1, OV2, OV3 is not possible.

FIG. 10 or FIG. 11 represent a potential solution to this issue. The switch device 1 is expanded by the inclusion of the input EPE and the output APE. At the input EPE, the ground conductor PE is connected which originates from the electrical energy source 4. At the output APE, connection of the ground conductor 10 is executed, which conductor is routed to the metallic housing 20 of the load 2, and is bonded to the housing 20 in an electrically conductive manner. In the switch device 1, the input EPE and the output APE are mutually connected in an electrically conductive manner. Additionally, in the switch device 1, a further short-circuiter SCSPE is incorporated which, on one side, is connected to an existing short-circuiter SCS1, SCS2 in an electrically conductive manner, in the present case to the short-circuiter SCS2 and, on the other side, is connected in an electrically conductive manner to the connection which is led through the switch device 1 from the input EPE to the output APE.

The broken line in FIG. 10 represents the current path of the ground fault current iSCPE1, in the event that the short-circuit occurs in the first electrical phase Ph1 within the load 2, vis-à-vis the metallic housing 20 of the load 2. If the ground fault is detected and switched-out, as represented in FIG. 11, two currents are formed, on the one hand a load-side ground fault current iSCPE1 and, on the other hand, a source-side ground fault current iSCPE2. Processes involved in the present case are analogous to those associated with the short-circuit according to FIG. 7.

As the inductances of the ground conductor PE, 10, both on the input side PE and on the output side 10, are comparable to those of the input connection lines 3 and of the load connection lines 5, the temporal characteristics of current i and voltage u behave in an analogous manner to FIGS. 8, which represents the case of a short-circuit within the load 2 between the first electrical phase Ph1 and the second electrical phase Ph2. The source-side ground fault current iSCPE2 decays rapidly, whereas the load-side ground fault current iSCPE1 flows for substantially longer before decaying to a zero value. Loading of the overvoltage limiting element OV1 is limited, which element, as described above, can again be dimensioned with a low rating.

As the ground conductor PE, 10 is led through the switch device 1, it is possible, by means of a current sensor 90, for the current iPE flowing in the ground conductor PE, 10 to be measured. In this manner, acquired measured values iMPE of the current iPE flowing through the ground conductor PE, 10 can be transmitted from the current sensor 90 to the control unit 8, where these values are employed for monitoring the condition of electrical insulation of the load side 2, comprised of the load connection lines and the load 2.

Advantageously, according to the solution represented in FIG. 11, by the monitoring of the current iPE1 in the ground conductor PE, 10 by means of a current sensor 90, the short-circuiter SCSPE acting on the ground conductor PE, 10 is only actuated, i.e. switched to an electrically conducting state, if required, i.e. only in the event of the presence of a ground fault, in combination with the other two short-circuiters SCS1 and SCS2, and can otherwise remain switched off at all times, i.e. switched to an electrically non-conducting state. As a result, leakage currents from the electrical phases Ph1, Ph2, Ph3 to the ground conductor PE, 10 can be minimized.

FIG. 12 shows a variant of a three-phase Ph1, Ph2, Ph3 switch device 1, in which each of the three short-circuiters SCSPE1, SCSPE2, SCSPE3 is routed to a current path 60 of the ground conductor connection which connects a fourth input EPE of the switch device 1, to which the ground conductor PE of the energy source is connected, to a fourth output APE of the switch device 1, to which the ground conductor 10 of the load is connected, wherein the three short-circuiters SCSPE1, SCSPE2, SCSPE3 assume a common connection point 12. This can be advantageous for the actuation of the short-circuiters SCSPE1, SCSPE2, SCSPE3 on the grounds that, as a result of the common connection point 12, a single actuation voltage can be simultaneously employed for all three short-circuiters SCSPE1, SCSPE2, SCSPE3. Disadvantageously, leakage currents via the ground conductor PE, 10 can be somewhat higher than in the variant according to FIG. 10.

FIG. 13 shows a further variant of the switch device 1. The switch device 1 is expanded by the inclusion of the input EN and the output AN for connecting a N-conductor 11 (N-conductor=neutral conductor). The neutral conductor 11 which originates from the electrical energy source is connected to the input EN. On the output AN, connection of the neutral conductor 11 is executed, which conductor is routed to the neutral conductor terminal of the load 2. In the switch device 1, the input EN and the output AN are electrically interconnected by means of a current path 60 of the neutral conductor connection. Each of the three outputs A1, A2, A3 is connectable to one short-circuiter SCSN1, SCSN2, SCSN3 on the current path 60 of the neutral conductor connection.

A switch device 1 having a neutral conductor terminal EN, AN enables a facility, in normal operation, for controlling loads 2 having a different energy take-up in each of the three electrical phases Ph1, Ph2, Ph3. The neutral conductor 11 ensures that, on each of the individual loads 2, the same voltage is applied in the three electrical phases Ph1, Ph2, Ph3. This enables a separate and independent control of three loads 2 in the electrical phases Ph1, Ph2, Ph3. Accordingly, each of the three loads 2 can be switched-on and switched-off at different time intervals, i.e. additionally, switching elements S1, S2, S3 can thus be switched-on and switched-off in a mutually independent manner.

Upon the switch-off of an electrical phase Ph1, Ph2, Ph3, in order to withhold the voltage generated by the load 2 from the switching element 1, a short-circuiter SCSN1, SCSN2, SCSN3 is connected from each output of the switch device 1 to the neutral conductor 11 in an electrically conductive manner. One short-circuiter SCSN1, SCSN2, SCNS3 is thus respectively assigned to each switching element S1, S2, S3, such that each switching element S1, S2, S3, independently of the circuit state of the other two switching elements, is protected in the event of switch-off. In the event of the detection of a short-circuit or a ground fault, the switching elements S1, S2, S3 are firstly switched off, and the short-circuiters SCSN1, SCSN2, SCSN3 are switched on thereafter.

By way of an example, in FIG. 13, a ground fault SCPE1 in the first electrical phase Ph1, within the load 2, vis-à-vis the metallic housing 20 is illustrated. The ground fault current iSCPE1 thus formed, prior to switch-off, is represented by a broken line. This current flows via the metal housing 20 of the load 2, via the ground conductor 10, via the electrical energy source and the input connection line 3, through the switching element S1 and through the output of the switch device 1 back to the location of the ground fault SCPE1.

Further to the switch-off of the switching element S1 and the subsequent switch-on of the short-circuiter SCSN1, two current paths are formed: in a first current path, the ground fault current iSCPE1 flows via the ground conductor 10 to the energy source 4, then via the input-side neutral conductor 11 into the switch device 1, and from thence via the short-circuiter SCSN1 to the output A1, and back to the location of the ground fault SCPE1. In the other, second current path, a current iSCPE2 also flows via the input-side neutral conductor 11 and the short-circuiter SCSN1, through the first overvoltage limiting element OV1 to the input E1, and back to the energy source 4.

Electrical conditions are very similar to those associated with a ground fault wherein the ground conductor PE, 10, according to FIG. 10 and FIG. 11, is connected to the switch device 1, such that the current and voltage characteristics are also very similar.

By way of distinction from FIG. 10 and FIG. 11, wherein the ground fault current iPE can be measured directly in the ground conductor PE, 10 and only flows in the event of a fault, a ground current measurement in the case of a connected neutral conductor 11 according to FIG. 13 is only possible in an indirect manner, and is consequently affected by a higher degree of inaccuracy. In this case, it is necessary for the ground fault current iSCPE1 to be ascertained by totalizing the measured values iM1, iM2, iM3, iM of the four currents i1, i2, i3 and iN flowing out of the switch device 1, by means of the control unit 8. If no ground fault in is force, in an ideal case, the total of these four currents i1, i2, i3 and iN will be equal to zero.

FIG. 14 shows a configuration according to which only one additional connection point is required: only one input connection point EPE is provided, to which the ground conductor PE, which originates from the energy source 4, is connected. The short-circuiters SCSPE1, SCSPE2, SCSPE3 are connected to this input terminal EPE on one side in the switch device 1. In the event of a ground fault, further to the switch-off of the switching elements S1, S2, S3 and the subsequent switch-on of the short-circuiters SCSPE1, SCSPE2, SCSPE3, two current paths are formed, both of which are routed via the input connection point EPE, via the short-circuiters SCSPE1, SCSPE2, SCSPE3, and through the switch device 1. The current paths are thus routed in an analogous manner to the current paths according to FIG. 13. According to this solution, however, no measurement of current in the ground conductor PE is possible during normal operation, and thus no routine monitoring of the condition of electrical insulation of the load.

FIG. 15 likewise shows a configuration having only one additional connection point on the switch device 1, namely, an input connection point EPE, wherein this configuration is only distinguished vis-à-vis FIG. 14 with respect to the arrangement of short-circuiters. According to this configuration, two short-circuiters SCS1, SCS2 are arranged between the three output terminals A1, A2, A3 of the switch device 1, and one short-circuiter SCSPE is routed from any of the output terminals A1, A2, A3 to the ground conductor terminal EPE. The advantage of the two configurations according to FIG. 14 and FIG. 15 is the economization of one device connection terminal, and thus a structurally simpler device layout.

The solution of the fundamental issue according to the invention has been represented, on the one hand, with reference to a short circuit within a load 2 between a first electrical phase Ph1 and a second electrical phase Ph2 and, on the other hand, by reference to a ground fault within a first electrical phase Ph1, vis-à-vis a grounded metallic housing 20 of the load 2. However, the solutions according to FIG. 10 to FIG. 15 will function for any arbitrary short-circuits and ground faults in the entire load circuit. It is thus intended that the occurrence of short-circuits between individual or multiple electrical phases, or of ground faults in one or more electrical phases vis-à-vis a grounded metallic conductor should be possible, without compromising the modes of operation described herein. The occurrence of short-circuits and ground faults should thus be manageable both in the load connection lines and within the load.

Multiple options are conceivable for the state of short circuiting switches in the time interval further to switch-off, and pending the time of the next switch-on:
Short-circuiting switches, further to the switch-off process, immediately the current flowing therein has assumed a zero value, can also be switched off, i.e. switched to a non-conducting state. In consequence, it is not necessary for the requisite actuation energy for the short-circuiting switches to be supplied, such that energy conversion of the switch device in the off-state is somewhat reduced.
Alternatively, however, the short-circuiting switches can also remain switched-on, i.e. switched to a conducting state, such that induced overvoltages in the load circuit, e.g. associated with other spatially proximal current circuits or associated with an indirect effect of lightning stroke, can be withheld from the semiconductor switches and the switch device.
A further potential option would be a time-limited switch-on of short-circuiting switches during the off-state of the switch device in the event that, during specific temporal phases, an overvoltage stress of the switch device is anticipated.

In each case, it is necessary for short-circuiting switches to be switched off immediately prior to the next switch-on of the switch device.

The key distinction of the solution according to the invention from conventional solutions is the incorporation of short-circuiting switches in the switch device, which switches short-circuit the outputs of the switch device further to the switch-out of a short-circuit, or further to a normal and regulation switch-off operation. As a result, overvoltage limiting elements, which are invariably required for switching elements in this type of assembly, can be dimensioned with a substantially lower rating.

In the absence of the short-circuiters provided according to the invention, it is necessary for overvoltage limiting elements to be dimensioned for a wide range of inductance which is dictated by the length of load connection lines and the type of load. Heavy-duty, voluminous and thus expensive overvoltage limiting elements are thus required, which elements significantly increase the structural space occupied by the switch device. Alternatively, it would be necessary for limiting conditions to be stipulated for the length of load connection lines and the type of load, which conditions must then be incorporated in operating instructions, thus restricting universal application.

In the case of a normal switch-off, the voltage generated by the load, particularly in the case of a motor, can result in an increased voltage stress of switching elements, which must consequently be rated for this purpose. The short-circuiters provided according to the invention prevent any perturbation of switching elements by voltages which are generated further to the switch-off of the load. Switching elements, with respect to the dielectric withstand thereof, can be dimensioned with a lower rating, which rating, firstly, is associated with cost advantages and, secondly, switching elements having a lower dielectric withstand generate lower electrical losses during the conduction of electric current, such that the evacuation of less heat is required. Cooling effort is reduced as a result, and smaller housings for switch devices are thus enabled.

In the exemplary embodiments according to FIG. 10, FIG. 12 and FIG. 13, in which the ground conductor or neutral conductor is led through the switch device, the current in the ground conductor or in the neutral conductor can be measured and the condition of electrical insulation of the connected load appraised on the basis thereof. This enables a prompt detection of insulation faults and the generation of a warning message for the attention of the operator of the switch device.

FIG. 16 shows a structural diagram representing an overview of various configurations 160α to 160λ which, on the basis of “structural” elements 160:“n phase conductors”, “neutral conductor” and “ground conductor”, can be present in a conductor system which is contacted by means of the switch device. Configurations are firstly distinguished according to the number n of phase conductors “Ph” of the power supply system. In a first single-phase leg 161, only a single phase conductor is present: n=1. In an alternative n-phase leg 162, multiple phase conductors are present: n>1.

In the event that the single-phase case 161 is in force (only one phase conductor Ph), there are two potential branches: either the phase conductor Ph and a neutral conductor N are present in a first branch 163 of the single-phase leg 161 or, in an alterative branch 164 of the single-phase leg 161, the phase conductor Ph, a neutral conductor N and a ground conductor E are present.
In the event that the first branch 163 is present, only configuration 160α exists, wherein a short-circuiter electrically connects the phase conductor Ph to the neutral conductor N.
In the event that the second branch 164 is present, either configuration 160β exists, wherein a short-circuiter electrically connects the phase conductor Ph to the neutral conductor N, or the configuration 160γ exists, wherein a short-circuiter electrically connects the phase conductor Ph to the ground conductor E.

In the event that the n-phase case 162 is in force (n phase conductors Ph1, . . . , Phn, where n is a whole number greater than one), there are four potential branches: in a first branch 165 of the n-phase leg 162, only the phase conductor Ph is present, in a second branch 166 of the n-phase leg 162 the phase conductor Ph and a neutral conductor N are present, in a third branch 167 of the n-phase leg 162 the phase conductor Ph and a ground conductor E are present, and in a fourth branch 168 of the n-phase leg 162, the phase conductor Ph, a neutral conductor N and a ground conductor E are present.
In the event that the first branch 165 is present, only configuration 160δ exists, wherein one or more short-circuiters electrically interconnect the phase conductors Ph.
In the event that the second branch 166 is present, either configuration 160ε exists, wherein one or more short circuiters electrically interconnect the phase conductors Ph, or configuration 160ζ exists, wherein one or more short-circuiters electrically connect the phase conductors Ph to the neutral conductor N.
In the event that the third branch 167 is present, either configuration 160η exists, wherein one or more short-circuiters electrically interconnect the phase conductors Ph, or configuration 160θ exists, wherein one or more short-circuiters electrically connect the phase conductors Ph to the ground conductor E.
In the event that the fourth branch 168 is present, firstly configuration 160ι exists, wherein one or more short-circuiters electrically interconnect the phases Ph, secondly configuration 160κ exists, wherein one or more short-circuiters connect the phase conductors Ph to the neutral conductor N, and thirdly configuration 160λ exists, wherein one or more short-circuiters electrically connect the phase conductors Ph to the ground conductor E.

1-15. (canceled)

16. A switch device for controlling an electrical energy flux from an energy source to a load, comprising:
n phase conductor inputs for electrically connecting to the energy source;
n phase conductor outputs for electrically connecting to the load;
n phase conductor current paths which, within the switch device, electrically connect said n phase conductor inputs to said n phase conductor outputs in a bijective arrangement;
n switching elements, wherein one of said n switching elements is respectively arranged in said n phase conductor current paths and enables a switching of a current flow in said phase conductor current paths; and
n overvoltage limiting elements, each connected in parallel with one of said n switching elements, with one of said overvoltage limiting elements being respectively assigned to each said switching element;
a control unit for actuating said switching elements; and
short-circuiting switches connected for actuation by said control unit and are arranged such that, in a current-conducting state thereof, said short-circuiting switches connect said n phase conductor outputs electrically conductively a) to one another and/or b) to a ground conductor or a neutral conductor of the energy source.

17. The switch device according to claim 16, which comprises:
an (n+1)^{th} input for electrically connecting to a ground conductor or a neutral conductor of the energy source;
wherein one or more of said short-circuiting switches are arranged such that, in a current-conducting state, said short-circuiting switches connect said n phase conductor outputs electrically conductively to said (n+1)^{th} input.

18. The switch device according to claim 17, which comprises:
an (n+1)^{th} output for electrically connecting to a ground conductor or to a neutral conductor of the load; and
an (n+1)^{th} current path which, within the switch device, electrically connects said (n+1)^{th} input to said (n+1)^{th} output, to form a ground or neutral conductor connection within the switch device.

19. The switch device according to claim 17 wherein a short-circuiting switch is routed from each of said n phase conductor outputs to said (n+1)^{th} input.

20. The switch device according to claim 17, further comprising a current measurement device for measuring a current in the ground or neutral conductor connection.

21. The switch device according to claim 20, wherein said control unit is configured, on a basis of a measured current in the ground conductor connection, to ascertain a condition of an electrical insulation of the load.

22. The switch device according to claim 20, wherein said control unit is configured, on a basis of a measured current in the neutral conductor connection, and in combination with measured currents flowing to said phase conductor outputs, to calculate a ground fault current that is employed for monitoring a condition of an electrical insulation of the load.

23. The switch device according to claim 16, further comprising:
current sensors for acquiring measured values of a current intensity in at least one of said current paths; and
transmitters for transmitting the measured values to said control unit.

24. The switch device according to claim 16, wherein said short-circuiting switches are electronic components.

25. A method for operating a switch device for controlling an electrical energy flux from an energy source to a load,
wherein n phase conductor current paths, in each of which a parallel-connected arrangement of a switching element and an overvoltage limiting element is arranged, within the switch device, electrically connect n phase conductor inputs of the switch device, which inputs are appropriate for electrically connecting to the energy source, to n phase conductor outputs of the switch device, which outputs are appropriate for electrically connecting to the load, in a bijective arrangement,
the method comprising the following steps:
actuating the switching elements, causing the switching elements to assume a current-conducting state and to enable a current flow via the respective current path;
interrupting the current flow in the current paths, wherein the switching elements are actuated to execute a switchover to a non-conducting circuit state thereof; and
subsequent to the switchover of the switching elements to the non-conducting state, actuating short-circuiting switches of the switch device to execute a switchover to a current-conducting circuit state, wherein short-circuiting switches are arranged in the switch device such that, in the current-conducting circuit state thereof, the short-circuiting switches connect the n phase conductor outputs of the switch device electrically conductively a) to one another and/or b) to a ground conductor or a neutral conductor of the energy source.

26. The method according to claim 25, further comprising the following steps:
measuring at least one of a current intensity or of a voltage in at least one of the phase conductor current paths;
transmitting measured values to a control unit of the switch device; and
transmitting, by the control unit, control commands to the switching elements and short-circuiting switches on a basis of the measured values.

27. The method according to claim 25, which comprises switching the switching elements to a non-conducting state when a short-circuit current occurs in one of the phase conductor current paths or when the load is to be switched off in a regular course.

28. The method according to claim 25, which comprises electrically conductively connecting, by way of one or more of the short-circuiting switches, the n phase conductor outputs of the switch device to an (n+1)^{th} input of the switch device, which input is appropriate for electrically connecting to a ground conductor or a neutral conductor of the energy source.

29. The switch device according to claim 28 which comprises establishing a connection from each of the above-mentioned n phase conductor outputs, by way of a respective short-circuiting switch, with the (n+1)^{th} input of the switch device, which input is appropriate for electrically connecting to a ground conductor or neutral conductor of the energy source.

30. The method according to claim 28, which comprises electrically connecting, by way of an (n+1)^{th} current path within the switch device, the (n+1)^{th} input of the switch device, which input is appropriate for electrically connecting to a ground conductor or a neutral conductor of the energy source, to an (n+1)^{th} output of the switch device, which output is appropriate for electrically connecting to a ground conductor or a neutral conductor of the load, thus forming a ground or neutral conductor connection within the switch device.
